(19) United States
(12) Patent Application Publication
(10) Pub. No.: US 2013/0252356 A1
(43) Pub. Date: Sep. 26, 2013

(54) SUPPORTING SUBSTRATE, METHOD FOR FABRICATING SEMICONDUCTOR DEVICE, AND METHOD FOR INSPECTING SEMICONDUCTOR DEVICE

(71) Applicant: KABUSHIKI KAISHA TOSHIBA, Tokyo (JP)

(72) Inventor: Akira EZAKI, Hyogo-ken (JP)

(73) Assignee: KABUSHIKI KAISHA TOSHIBA, Tokyo (JP)

(21) Appl. No.: 13/789,517

(22) Filed: Mar. 7, 2013

(30) Foreign Application Priority Data
Mar. 22, 2012 (JP) 2012-065934

(51) Int. Cl. H01L 21/683

(52) U.S. Cl. CPC H01L 21/683; H01L 22/12
USPC 438/18; 269/302

(57) ABSTRACT

An aspect of one embodiment, there is provided a supporting substrate, including a first supporting substrate, an outer diameter being larger than a diameter of a semiconductor substrate and an inner diameter being smaller than the diameter of the semiconductor substrate, and a second supporting substrate, an outer diameter being smaller than the inner diameter of the first supporting substrate.

### CROSS REFERENCE TO RELATED APPLICATION

This application is based upon and claims the benefit of priority from prior Japanese Patent Application No. 2012-065934, filed on Mar. 22, 2012, the entire contents of which are incorporated herein by reference.

### FIELD

An exemplary embodiment described herein relates to a supporting substrate, a method for manufacturing a semiconductor device, and a method for inspecting the semiconductor device.

### BACKGROUND

In a vertical semiconductor device such as a discrete semiconductor, a semiconductor substrate (hereinafter referred to as a wafer) is reduced in thickness by grinding, polishing, etching, or the like from the back surface, and then various process treatments are applied to the back surface of the wafer. After the process treatments, in general, the electrical characteristics are inspected and the semiconductor device is divided into discrete pieces. However, the wafer is significantly warped by lowering of the strength due to the reduction in thickness of the wafer, stress due to a structure of the semiconductor device formed on the wafer, and the like. Thus, conveyance (handling, for example) of the wafer becomes difficult. Moreover, failure (cracking and breaking, for example) in the conveyance and processing of the wafer easily occurs.

Thus, there has been adopted a method in which various process treatments are applied on the back surface of the wafer in such a state that a surface protection sheet (hereinafter referred to as a BSG tape) or a supporting substrate is attached to the front surface of the wafer. As an example of the conventional supporting substrate, there has been known one having a plurality of through holes penetrating the back surface from the front surface to the back surface. By virtue of the formation of the plurality of through holes, a solvent used when the supporting substrate is removed from the front surface of the wafer can be rapidly introduced into the entire region between the supporting substrate and the front surface of the wafer.

Meanwhile, in electrical characteristic inspection after the various process treatments applied to the back surface of the wafer and the formation of a back surface electrode on the back surface of the wafer, it is necessary to bring a probe of an electric characteristic inspection apparatus into contact with a front surface electrode on the front surface side of the wafer and bring a test stage of the electric characteristic inspection apparatus into contact with the back surface electrode on the back surface side of the wafer. However, in such a state that the BSG tape or a glass substrate is applied on the front surface of the wafer, the probe cannot be brought into contact with the front surface electrode. Thus, when the electrical characteristics of the semiconductor device are inspected, the BSG tape or the glass substrate applied on the wafer front surface is removed to expose the front surface electrode.

Generally, the BSG tape or the glass substrate is removed while the wafer is mounted on a dicing sheet. However, when the BSG tape or the glass substrate is removed, the strength of the wafer is required to be maintained and thus the dicing sheet cannot be removed. Accordingly, the test stage cannot be in contact with the back surface electrode. Thus, there has been proposed that a ring-shaped tape having a circular opening at the center is applied on the wafer front surface, and the electric characteristics of the semiconductor device is inspected in such a state that the front surface electrode is exposed.

However, in a conventional method, a wafer cannot be reinforced consistently from the reduction in thickness of the wafer to the inspection of the electric characteristics of the semiconductor device.

### BRIEF DESCRIPTION OF THE DRAWINGS

FIGS. 1A to 1C are respectively an overhead view, a plan view, and a cross-sectional view showing a configuration of a supporting substrate according to an embodiment:

FIGS. 2A to 2C are cross-sectional views showing a method for fabricating a semiconductor device using the supporting substrate according to the embodiment:

FIGS. 3A to 3C are cross-sectional views showing the method for fabricating the semiconductor device using the supporting substrate according to the embodiment:

FIGS. 4A to 4D are cross-sectional views showing the method for fabricating the semiconductor device using the supporting substrate according to the embodiment.

### DETAILED DESCRIPTION

An aspect of one embodiment, there is provided a supporting substrate, including a first supporting substrate, an outer diameter being larger than a diameter of a semiconductor substrate and an inner diameter being smaller than the diameter of the semiconductor substrate, and a second supporting substrate, an outer diameter being smaller than the inner diameter of the first supporting substrate.

An aspect of another embodiment, there is provided a method for fabricating a semiconductor device, including applying a first supporting substrate and a second supporting substrate on a surface having semiconductor devices of a semiconductor substrate, an outer diameter of the first supporting substrate being larger than a diameter of a semiconductor substrate and an inner diameter of the first supporting substrate being smaller than the diameter of the semiconductor substrate and an outer diameter of the second supporting substrate being smaller than the inner diameter of the first supporting substrate, grinding a back surface of the substrate to be thinned in thickness of the semiconductor substrate; removing the second supporting substrate from the surface of the semiconductor substrate, inspecting electrical characteristics of the semiconductor devices, attaching a dicing sheet on the back surface of the semiconductor substrate, removing the first supporting substrate from the surface of the semiconductor substrate, and dicing to divide the semiconductor substrate into discrete pieces of the semiconductor devices.

An aspect of another embodiment, there is provided a method for inspecting the semiconductor device, including applying a first supporting substrate and a second supporting substrate on a surface having semiconductor devices of a semiconductor substrate, an outer diameter of the first supporting substrate being larger than a diameter of a semiconductor substrate and an inner diameter of the first supporting substrate being smaller than the diameter of the semiconductor substrate and an outer diameter of the second supporting substrate being smaller than the inner diameter of the first supporting substrate, grinding a back surface of the substrate to be thinned in thickness of the semiconductor substrate, removing the second supporting substrate from the surface of the semiconductor substrate, and inspecting electrical characteristics of the semiconductor devices.

Hereinafter, an embodiment will be described in detail with reference to the drawings.

### EMBODIMENT

<Configuration of Supporting Substrate 100>

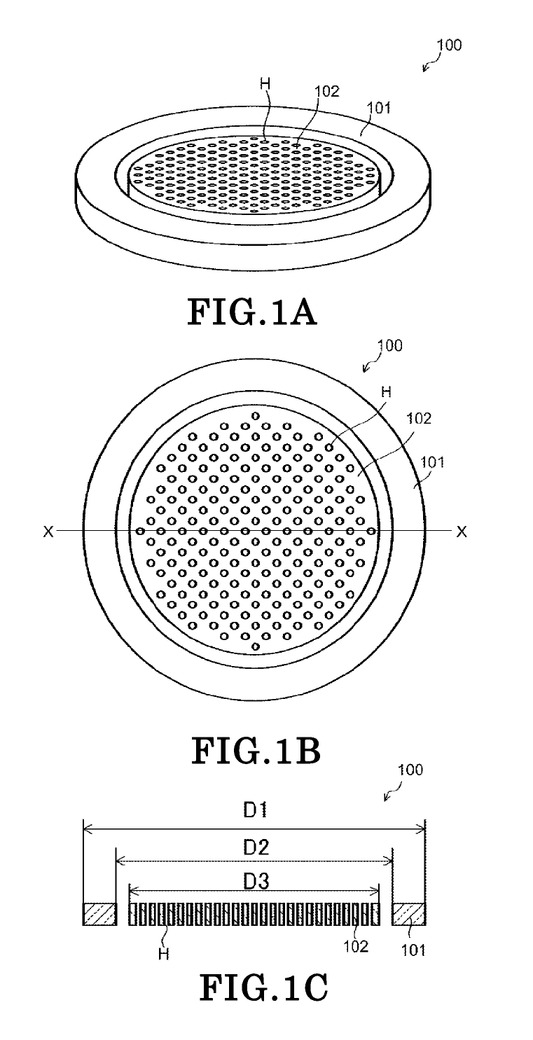

A configuration of a supporting substrate 100 will be described. FIGS. 1A to 1C are respectively a perspective view, a plan view, and a cross-sectional view showing the configuration of the supporting substrate according to the embodiment. FIG. 1A is an overhead view of the supporting substrate 100. FIG. 1B is a plan view of the supporting substrate 100. FIG. 1C is a cross-sectional view of the supporting substrate 100 taken along X-X line of FIG. 1B.

When a back surface of a semiconductor substrate W (hereinafter referred to as a wafer W) on which the semiconductor device is formed is polished to be reduced in thickness, or after the wafer W is reduced in thickness, the supporting substrate 100 is used as a reinforcing plate of the wafer W until inspection of the electric characteristics of the semiconductor device formed on the wafer W by dicing. The supporting substrate 100 has a first supporting substrate 101 and a second supporting substrate 102. The first and second supporting substrates are formed by being cut out from a glass or metal plate. The thickness and material of the first and second supporting substrates are the same.

The first supporting substrate 101 is a ring-shaped supporting substrate having a circular opening at the center. The first supporting substrate 101 has an outer diameter D1 larger than the diameter of the wafer W to be supported and an inner diameter D2 smaller than the diameter of the wafer W. Specifically, it is preferable that the outer diameter D1 of the first supporting substrate 101 is larger by approximately 20 mm than the diameter of the wafer W, and the inner diameter D2 is smaller by approximately 2 to 6 mm (one side: 1 to 3 mm) than the diameter of the wafer W.

For example, when the wafer W with a diameter of 200 mm is supported, it is preferable that the outer diameter D1 of the first supporting substrate 101 is approximately 220 mm, and the inner diameter D2 is approximately 196 mm. The outer diameter of the supporting substrate 101 is made larger than the diameter of the wafer W, because a margin of a length for absorption and the like is secured when a surface protection tape (hereinafter referred to as a BSG tape) applied on the front surface of the supporting substrate 100 is removed in the reduction in thickness of the wafer W.

The inner diameter D2 is made smaller than the diameter of the wafer W, because a margin of a length for adhesion is secured when the first supporting substrate 101 is joined to the wafer W. The inner diameter D2 is made smaller by 2 to 6 mm, preferably approximately 4 mm (one side: 2 mm) than the diameter of the wafer W, because in the joining, an adhesive for temporary fixing or the back surface of the first supporting substrate 101 is prevented from being in contact with the semiconductor device formed on the wafer W.

The semiconductor device is not formed in a region of several mm (usually, approximately 3 mm) at the end of the wafer W. The inner diameter D2 of the first supporting substrate 101 is smaller by 2 to 6 mm (preferably 4 mm) than the diameter of the wafer W, whereby the contact of the first supporting substrate 101 with the semiconductor device and the occurrence of failure of the semiconductor device due to adhesion with the temporary fixing adhesive, such as deposition of dust, the occurrence of flaws, and non-conduction of an electrode are prevented as much as possible.

In the second supporting substrate 102, an outer diameter D3 is not more than the inner diameter D2 of the first supporting substrate 101. For example, when the diameter of the wafer W to be supported is 200 mm, the outer diameter D3 of the second supporting substrate 102 is preferably approximately 194 mm. When the outer diameter D3 of the second supporting substrate 102 is not more than the inner diameter D2 of the first supporting substrate 101, the second supporting substrate 102 can be disposed in the opening of the first supporting substrate 101.

In the second supporting substrate 102, through holes H with a diameter φ of 0.4 mm penetrating from a front surface F to a back surface B are formed as a matrix at pitches (intervals) of 0.8 mm. By virtue of the formation of the plurality of through holes H on the second supporting substrate 102, a removing solution used in a removing process of the second be supporting substrate 102 is rapidly supplied between the back surface of the second supporting substrate 102 and the front surface of the wafer W. Consequently, the second supporting substrate 102 can be removed more easily in a shorter time than ever before.

<Formation of Supporting Substrate 100>

A method of forming the supporting substrate 100 will be described. In the following description, the formation of a supporting substrate for a wafer with a diameter of 200 mm will be described.

(1) A plate (a metal plate or a glass plate, for example) having a uniform thickness is prepared.
(2) A circular plate (first circular plate) with a diameter of 220 mm is cut out from the above-described plate using a blade rotating at high speed.
(3) A circular plate (second circular plate) with a diameter of 194 mm is cut out concentrically from the first circular plate using a blade rotating at high speed.
(4) A plurality of through holes H penetrating from the front surface F to the back surface B, having a diameter φ of 0.4 mm, and arranged at intervals of 0.8 mm pitch are formed as a matrix on the second circular plate.

When the second circular plate is cut out, a blade having a diameter of 60 mm and a thickness of 200 μm (0.2 mm) is used. When cutting-out is performed while the blade is abutted against a position where the diameter becomes 195 mm, a circular plate having a diameter of approximately 194 mm can be cut out. A resist film is coated on the second circular plate and then exposed, and further developed. A plurality of holes, each having a diameter φ of 0.4 mm, are arranged at intervals of 0.8 mm pitch to be formed in the form of a matrix on the resist. After the process described above, the blast treatment is performed. In such a manner, the through holes H of the second circular plate are formed.

<Method for Manufacturing Semiconductor Device Using Supporting Substrate 100>

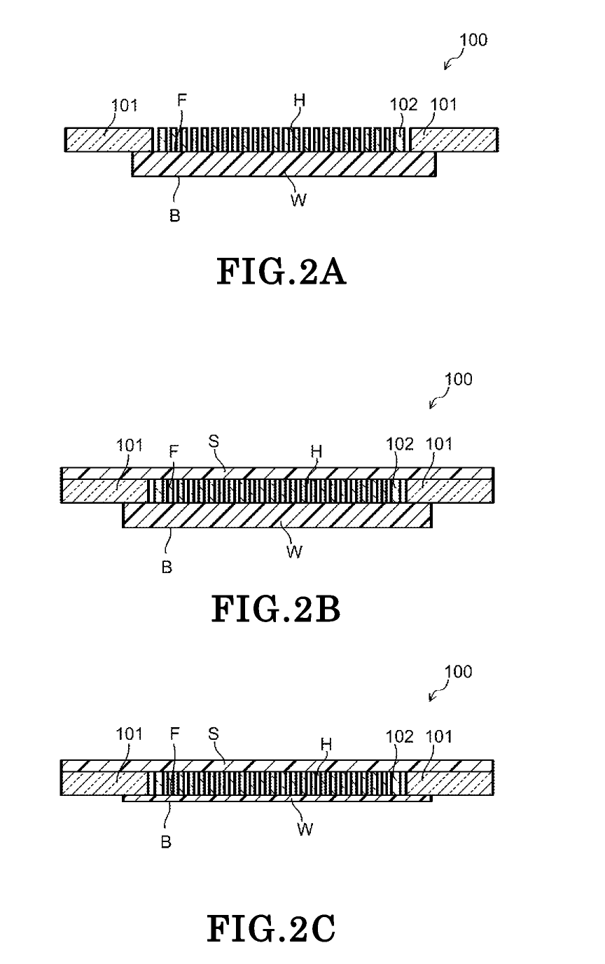

FIGS. 2A to 4C are cross-sectional views showing a fabricating process of the semiconductor device using the supporting substrate according to the embodiment. Hereinafter, a method for fabricating a semiconductor device using the supporting substrate 100 will be described with reference to FIGS. 2A to 4C.

As shown in FIG. 2A, the supporting substrate 100 is applied on the front surface F of the wafer W with a thickness of approximately 725 μm on which the semiconductor device is formed.

As shown in FIG. 2B, a BSG tape S is applied on the front surface of the supporting substrate 100.

As shown in FIG. 2C, the back surface B of the wafer W is grinded and subjected to spin wet etching, and the thickness of the wafer W is reduced to approximately 30 μm.

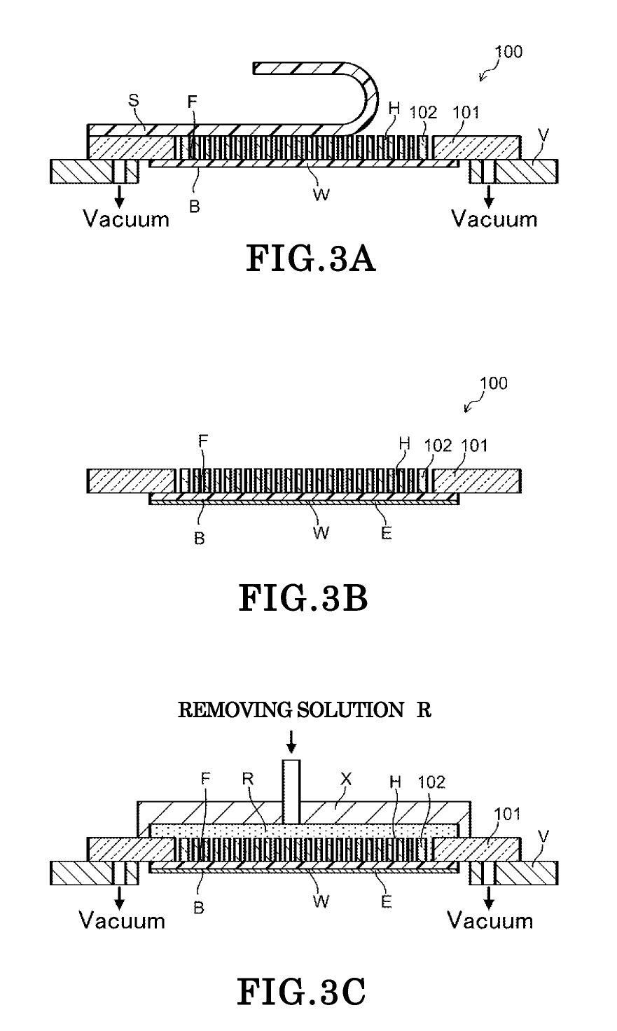

The end of the back surface of the first supporting substrate 101 (the side on which the wafer W is applied) is subjected to vacuum suction using a ring-shaped absorption jig V having an outer diameter larger than the outer diameter D1 of the first supporting substrate and an inner diameter larger than the diameter of the wafer W, whereby the first supporting substrate 101 is supported. As shown in FIG. 3A, the BSG tape S applied on the front surface of the supporting substrate 100 is removed in such a state that the first supporting substrate is supported. According to the method, the BSG tape S can be removed without touching the front surface F of the wafer W.

As shown in FIG. 3B, the back surface B of the thinned wafer W is subjected to process treatments such as ion implantation, diffusion (laser annealing), and formation of a back surface electrode E (sputtering using PVD (physical vapor deposition) apparatus).

The end of the back surface of the first supporting substrate 101 is subjected to vacuum suction by the absorption jig V to support the first supporting substrate 101. Next, as shown in FIG. 3C, a removing solution R is introduced into the through holes H formed on the second supporting substrate 102 and a gap between the first supporting substrate 101 and the second supporting substrate 102. At this time, since the front surface F of the wafer W filled with the removing solution R is surrounded by the first supporting substrate 101, the removing solution R can be prevented from being spilled outside the wafer W.

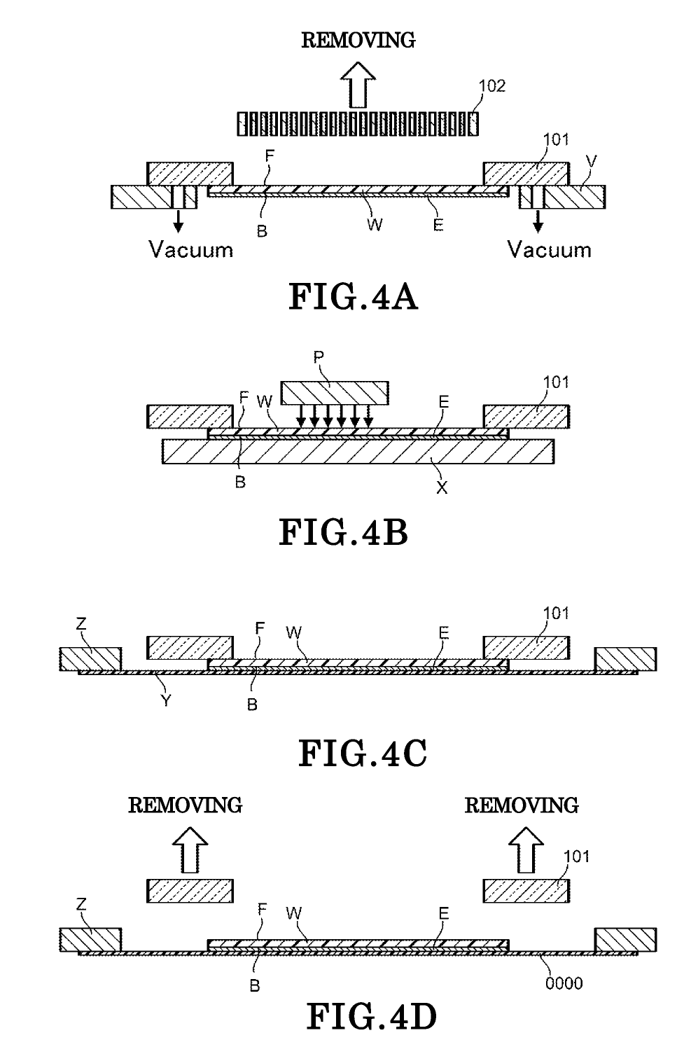

As shown in FIG. 4A, the second supporting substrate 102 is removed from the front surface F of the wafer W. In the removal of the second supporting substrate 102, a separation and washing apparatus is used. After the removal of the second supporting substrate 102, the front surface F of the wafer W is cleaned to remove an adhesive for temporary fixing from the front surface F of the wafer W. When the front surface F of the wafer W is cleaned, the first supporting substrate 101 can prevent a washing liquid from being spilled outside the wafer W.

A probe P of an electric characteristic inspection apparatus is brought into contact with a front surface electrode (not shown) of the front surface F of the wafer W exposed by removing the second supporting substrate 102. Moreover, as shown in FIG. 4B, a test stage X of the electric characteristic inspection apparatus is brought into contact with the back surface electrode E formed on the back surface B of the wafer W, and the electric characteristics of the semiconductor device are measured.

As shown in FIG. 4C, after the measurement of the electric characteristics, a jig for dicing formed by a dicing sheet Y and a frame Z holding the dicing sheet Y is attached to the back surface B of the wafer W.

The first supporting substrate 101 is removed from the front surface F of the wafer W (see FIG. 4D). The first supporting substrate 101 and the front surface F of the wafer W are just adhered by about 2 mm on the outer circumference with a temporary fixing agent. Thus, when the first supporting substrate 101 is lifted and a portion of the first supporting substrate 101 is removed, the removed portion triggers progress of removal. Thus, the first supporting substrate 101 can be easily removed from the front surface F of the wafer W even when a remover is not used. Needless to add, the first supporting substrate 101 may be removed from the front surface F of the wafer W by using the remover.

The wafer W is subjected to dicing to divide the semiconductor device into discrete pieces. The semiconductor device may be divided into discrete pieces by full-cutting the wafer W, or after the wafer W is half-cut, the dicing sheet Y may be extended to divide the semiconductor device into discrete pieces. When the first supporting substrate 101 is removed, the temporary fixing agent remaining around the front surface F of the wafer W exists in a region where the semiconductor device is not formed (outside an effective region). Thus, the wafer W is subjected to dicing without cleaning the temporary fixing agent remaining around the front surface F of the wafer W, and the semiconductor device can be divided into discrete pieces.

As described above, by virtue of the use of the supporting substrate 100 according to the embodiment, the process from the reduction in thickness of the wafer to the inspection of the electric characteristics of the semiconductor device can be performed in such a state that the wafer W is always reinforced.

A plate (a metal plate or a glass plate, for example) having a uniform thickness is cut to form the first supporting substrate 101 and the second supporting substrate 102. Accordingly, when the first and second supporting substrates 101, 102 are applied on the front surface F of the wafer W, a step formed between the first and second supporting substrates 101, 102 can be reduced as possible. Thus, the first and second supporting substrates 101, 102 are applied on the front surface F of the wafer W, and, when the thickness of the wafer W is reduced by polishing, a stress concentration on a portion (step portion) of the wafer W can be suppressed, and the occurrence of crack and breaking of the wafer W can be reduced. Moreover, the supporting substrate 100 can be formed at low cost.

When the BSG tape S is removed, it is unnecessary to touch the back surface B of the wafer W. Therefore, adhesion of foreign matters (dust) to the back surface B of the wafer W whose thickness has been reduced can be suppressed. Thus, in the ion implantation and annealing after the reduction in thickness of the wafer W, it is possible to prevent a region where the ion implantation cannot be performed (defects in an active layer) from being formed in a portion of the wafer W due to the foreign matters used as a mask. Further, since an occurrence of flaws due to contact with the back surface B of the wafer W can be suppressed, an occurrence of breaking and crack of the wafer W due to the flaws can be reduced. Thus, the process treatment can be stably applied to the back surface B of the wafer W whose thickness has been reduced.

Furthermore, since the second supporting substrate 102 is removed in such a state that the first supporting substrate 101 surrounds the periphery of the front surface F of the wafer W, the possibility of spilling a removing solution and a cleaning solution from the wafer W can be reduced. Thus, the possibility of contaminating a peeling apparatus and the back surface B of the wafer W with the removing solution and the cleaning solution can be reduced. In the prior art, the dicing sheet Y is applied on the back surface B of the wafer W, and the supporting substrate is then removed. However, the removing solution sometimes is in contact with the dicing sheet Y to melt the dicing sheet Y. Namely, since a thinner-based solvent is generally used as the removing solution, a dicing sheet formed of vinyl chloride resin and so on is melted by the removing solution. However, in the method according to the embodiment, since the removing solution is not in contact with the dicing sheet Y, there is no possibility that the dicing sheet Y is melted. Such a feature also applies to the cleaning solution.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification.

What is claimed is:

1. A supporting substrate, comprising:
a first supporting substrate, an outer diameter being larger than a diameter of a semiconductor substrate and an inner diameter being smaller than the diameter of the semiconductor substrate; and
a second supporting substrate, an outer diameter being smaller than the inner diameter of the first supporting substrate.

2. The supporting substrate of claim 1, wherein
the inner diameter is smaller than the diameter of the semiconductor substrate 2-6 mm.

3. The supporting substrate of claim 1, wherein
a plurality of through holes penetrates between a front surface and a back surface of the second supporting substrate.

4. The supporting substrate of claim 1, wherein
the second supporting substrate has the same material and thickness as the first supporting substrate.

5. The supporting substrate of claim 1, wherein
the second supporting substrate is cut out to be formed from the same plate as the first supporting substrate.

6. A method for fabricating a semiconductor device, comprising:
applying a first supporting substrate and a second supporting substrate on a surface having semiconductor devices of a semiconductor substrate, an outer diameter of the first supporting substrate being larger than a diameter of a semiconductor substrate and an inner diameter of the first supporting substrate being smaller than the diameter of the semiconductor substrate and an outer diameter of the second supporting substrate being smaller than the inner diameter of the first supporting substrate;
grinding a back surface of the substrate to be thinned in thickness of the semiconductor substrate;
removing the second supporting substrate from the surface of the semiconductor substrate;
inspecting electrical characteristics of the semiconductor devices;
attaching a dicing sheet on the back surface of the semiconductor substrate;
removing the first supporting substrate from the surface of the semiconductor substrate; and
dicing to divide the semiconductor substrate into discrete pieces of the semiconductor devices.

7. The method of claim 6, wherein
in the inspecting of the electrical characteristics, the electrical characteristics are measured by contacting a probe of an electric characteristic inspection apparatus on an exposed surface of the semiconductor substrate and contacting a test stage of the electric characteristic inspection apparatus on the back surface of the semiconductor substrate.

8. The method of claim 6, wherein
in the removing the second supporting substrate, removing solution is supplied inside the first supporting substrate.

9. The method of claim 6, further comprising:
after the applying of the first supporting substrate and the second supporting substrate, applying a surface protection tape on a surface of the first supporting substrate and a surface of the second supporting substrate, and after the grinding of the back surface of the substrate, removing the surface protection tape from the surfaces of the first supporting substrate and the second supporting substrate.

10. The method of claim 9, wherein
in removing the surface protection tape, the surface protection tape is removed in a state that a back surface of the first supporting substrate is suctioned.

11. The method of claim 6, wherein
the inner diameter is smaller than the diameter of the semiconductor substrate 2-6 mm.

12. The method of claim 6, wherein
a plurality of through holes penetrates between a front surface and a back surface of the second supporting substrate.

13. A method for inspecting a semiconductor device, comprising:
applying a first supporting substrate and a second supporting substrate on a surface having semiconductor devices of a semiconductor substrate, an outer diameter of the first supporting substrate being larger than a diameter of a semiconductor substrate and an inner diameter of the first supporting substrate being smaller than the diameter of the semiconductor substrate and an outer diameter of the second supporting substrate being smaller than the inner diameter of the first supporting substrate;
grinding a back surface of the substrate to be thinned in thickness of the semiconductor substrate;
removing the second supporting substrate from the surface of the semiconductor substrate; and
inspecting electrical characteristics of the semiconductor devices.

14. The method of claim 13, wherein
in the inspecting of the electrical characteristics, the electrical characteristics are measured by contacting a probe of an electric characteristic inspection apparatus on an exposed surface of the semiconductor substrate and contacting a test stage of the electric characteristic inspection apparatus on the back surface of the semiconductor substrate.

15. The method of claim 13, wherein
in the removing the second supporting substrate, removing solution is supplied inside the first supporting substrate.

16. The method of claim 13, further comprising:
after the applying of the first supporting substrate and the second supporting substrate, applying a surface protection tape on a surface of the first supporting substrate and a surface of the second supporting substrate, and after the grinding of the back surface of the substrate, removing the surface protection tape from the surfaces of the first supporting substrate and the second supporting substrate.

17. The method of claim 13, wherein
in removing the surface protection tape, the surface protection tape is removed in a state that a back surface of the first supporting substrate is suctioned.

18. The method of claim 13, wherein
the inner diameter of the first supporting substrate is smaller than the diameter of the semiconductor substrate 2-6 mm.

19. The method of claim 13, wherein
a plurality of through holes penetrates between a front surface and a back surface of the second supporting substrate.
